(19) United States
(12) Patent Application Publication
(10) Pub. No.: US 2020/0395199 A1
(43) Pub. Date: Dec. 17, 2020

(54) SUBSTRATE TREATMENT APPARATUS AND METHOD OF CLEANING INSIDE OF CHAMBER

(71) Applicant: ASM IP Holding B.V., Almere (NL)

(72) Inventor: Ryo MIYAMA, Tokyo (JP)

(73) Assignee: ASM IP Holding B.V., Almere (NL)

(21) Appl. No.: 16/859,522

(22) Filed: Apr. 27, 2020

Related U.S. Application Data
(60) Provisional application No. 62/861,611, filed on Jun. 14, 2019.

(51) Int. Cl. H01J 37/32; H03H 7/38; B08B 7/00; C23C 16/44; C23C 16/458; C23C 16/50

(52) U.S. Cl. CPC H01J 37/32862; H01J 37/32724; H01J 37/32183; H03H 7/38; H01J 2237/335; C23C 16/4405; C23C 16/4583; C23C 16/50; B08B 7/0035

(57) ABSTRACT

Examples of a substrate treatment apparatus includes a chamber, a susceptor provided in the chamber and having an electrode therein, a metal plate facing the susceptor, a plurality of impedance adjusters having different impedances, and a selection device configured to connect one of the plurality of impedance adjusters to the electrode.

### TECHNICAL FIELD

Examples are described which relate to a substrate treatment apparatus and a method of cleaning the inside of a chamber.

### BACKGROUND

A method of cleaning the inside of a chamber in CVD (Chemical Vapor Deposition) or ALD (Atomic Layer Deposition) can be roughly classified into a remote plasma method and a direct plasma method. In remote plasma cleaning carried out with a halogen such as NF₃, cleaning on remaining areas other than an area between an RE electrode and a susceptor can also be facilitated. However, in an HM carbon process, for example, the film forming temperature is as high as 500° C. or higher, causing a damage to chamber parts. In remote plasma cleaning carried out with only oxygen, for example, active species are likely to be deactivated, resulting in inefficiency in cleaning.

On the other hand, in direct plasma cleaning carried out with oxygen plasma, for example, since plasma and active species are basically only generated between an RF electrode and a susceptor, cleaning efficiency lowers in other areas. For example, cleaning on a lower part of the susceptor or inside an exhaust duct that encloses the susceptor can be insufficient. If the inside of a chamber is not appropriately cleaned, particles may be generated in the chamber. In addition, inefficient cleaning reduces throughput.

### SUMMARY

Some examples described herein may address the above-described problems. Some examples described herein may provide a substrate treatment apparatus and a cleaning method, which make it possible to clean a wide range in a chamber.

In some examples, a substrate treatment apparatus includes a chamber, a susceptor provided in the chamber and having an electrode therein, a metal plate facing the susceptor, a plurality of impedance adjusters having different impedances, and a selection device configured to connect one of the plurality of impedance adjusters to the electrode.

### BRIEF DESCRIPTION OF THE DRAWINGS

FIG. 1 shows a configuration example of a substrate treatment apparatus;

FIG. 2A shows a configuration example of a plurality of impedance adjusters;

FIG. 2B shows another example of a plurality of impedance adjusters;

FIG. 3A shows yet another example of a plurality of impedance adjusters;

FIG. 3B shows still yet another example of a plurality of impedance adjusters;

FIG. 4 shows plasma in plasma treatment or a normal cleaning by using the first impedance adjuster;

FIG. 5 shows plasma in wide-range cleaning by using the second impedance adjuster; and

FIG. 6 shows a configuration example of a plurality of impedance adjusters according to another example.

### DETAILED DESCRIPTION

A substrate treatment apparatus and a method of cleaning the inside of a chamber will be described with reference to drawings. The same reference signs may be used for the same or corresponding components, thereby omitting redundant descriptions.

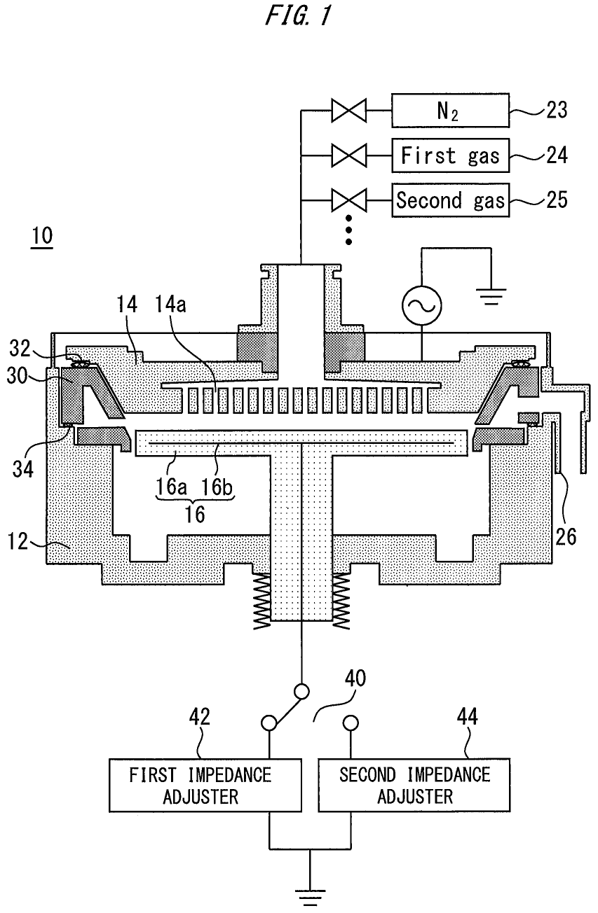

FIG. 1 illustrates a configuration example of a substrate treatment apparatus 10 according to an embodiment. This substrate treatment apparatus 10 includes a chamber 12 and a susceptor 16 in the chamber 12. The susceptor 16 includes a base 16a and an electrode 16b inside the base 16a. The base 16a is, for example, of a carbon-based material such as SiC, a graphite material, or ceramic. Most part of the electrode 16b is embedded in this base 16a. A susceptor heater can be provided inside or on the periphery of the base 16a. On the susceptor 16, a metal plate 14 facing the susceptor 16 is provided. The metal plate 14 is provided with slits 14a. The susceptor 16 and metal plate 14 provide a parallel flat-plate structure. To the metal plate 14, an AC power supply is connected. The AC power supply applies, for example, HRF (High-RF) and LRF (Low-RF) to the metal plate 14. The frequency of HRF is, for example, 13.56 MHz or 27 MHz; and the frequency of LRF is, for example, 5 MHz or 400-500 kHz.

An exhaust duct 30 is mounted on the chamber 12 via an O ring 34. The exhaust duct 30 can be shaped so as to enclose the susceptor 16. On the exhaust duct 30, the metal plate 14 is mounted via an O ring 32.

In FIG. 1, three gas sources 23, 24, and 25 are illustrated. Gas is supplied into a space between the susceptor 16 and metal plate 14 via the slits 14a of the metal plate 14 from these gas sources 23, 24, and 25. The gas is used for substrate treatment or cleaning, for example. In this example, the metal plate 14 is a high-frequency electrode to which an RF power is applied and is also a shower head for supplying the gas through the slits 14a. In another example, gas can be supplied into a space between the metal plate and the susceptor from any position. Gas having been used for a process such as substrate treatment or cleaning is guided to the exhaust port 26 through the exhaust duct 30.

This substrate treatment apparatus 10 includes a plurality of impedance adjusters having different impedances. In an example in FIG. 1, a first impedance adjuster 42 and a second impedance adjuster 44 are provided as examples of the plurality of impedance adjusters. For connection of one of the plurality of impedance adjusters to the electrode 16b, a selection device 40 is provided. The selection device 40 is, for example, a switch. In the example in FIG. 1, the selection device 40 makes the first impedance adjuster 42 and electrode 16b connected. As shown in FIG. 1, the first impedance adjuster 42 and the second impedance adjuster 44 are grounded. Means for grounding can be, for example, contact with a ground metal, contact with a ground terminal, or contact with the chamber 12.

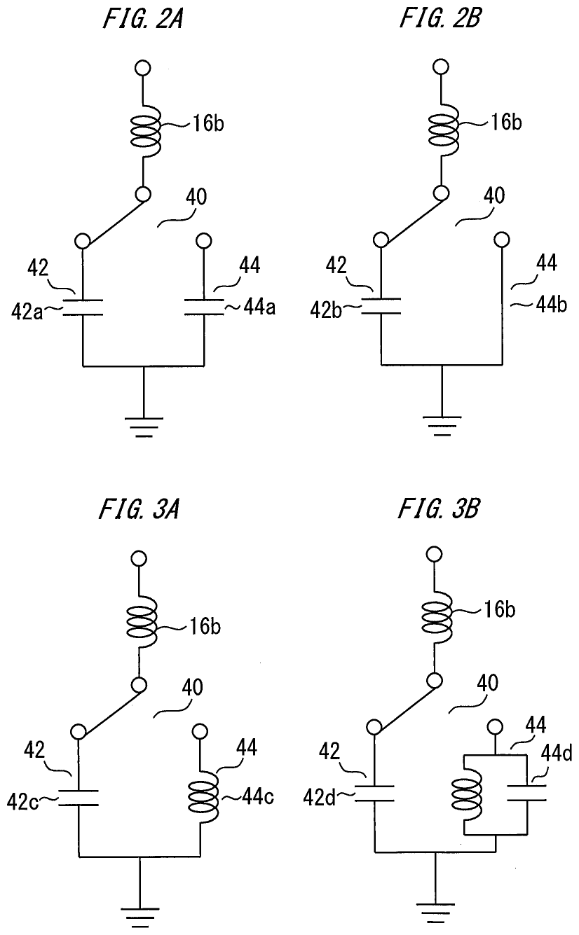

FIG. 2A is a circuit diagram showing a configuration example of a plurality of impedance adjusters. The electrode 16b has an inductance component and therefore, is illustrated as an inductor. In the example in FIG. 2A, the plurality of impedance adjusters includes: a first impedance adjuster 42 having a first capacitor 42a; and a second impedance adjuster 44 having a second capacitor 44a.

The impedance Z is represented by the following using the resistance R and the reactance X:

Z=R+jX

In addition, the impedance Z_{L} due to an inductance component included in the electrode 16b and the impedance Zc due to a capacitor connected to the electrode 16b are represented by the following:

Z_{L}=jX_{L}=jωL

Z_{C}=jX_{C}=1/(jωC)=−j/(ωC)

where

the letter L is an inductance of the electrode 16b;

the symbol ω is the angular frequency of an RF power applied to the metal plate 14, i.e. 2πf, and

the letter C is the capacitance of the capacitor connected to the electrode 16b.

Further, the inductance L is determined by the shape of the electrode 16b.

The impedance from the susceptor 16 to a GND is obtained by the sum of the impedance Z_{L} and impedance Zc. When plasma treatment is applied to a substrate placed on the susceptor 16 or a normal cleaning is performed within the chamber, plasma is generated between parallel flat-plates and plasma generation in other parts is suppressed. In this case, Z_{L}+Z_{C} is set to a lower value. In the example in FIG. 2A, the capacitance C_{A} of the first capacitor 42a is adjusted so as to obtain lower Z_{L}+Z_{C}. When the impedance provided by the capacitance C_{A} is defined as Z_{CA}, Z_{L}+Z_{CA} is to be set to be a smaller value. Concretely, the sum of the impedance of the first impedance adjuster 42 and the impedance of the electrode 16b is set to be smaller than the impedance of the electrode 16b. In this example, the capacitance C_{A} is designed so as to obtain Z_{L}+Z_{CA}<Z_{L}, the electrode 16b and the first impedance adjuster 42 are connected by the selection device 40, and the susceptor 16 is made to function as a GND, thereby causing a discharge between the metal plate 14 and the susceptor 16. Gas is supplied between the parallel flat-plates and an RF power is applied to the metal plate 14 to generate plasma between the parallel flat-plates.

When plasma is generated by connecting the electrode 16b and the first impedance adjuster 42 by the selection device 40, it means that plasma is generated only between the parallel flat-plates. In this case, the capacitance C_{A} is adjusted so that Z_{L} and Z_{CA} are compensated with each other to make Z_{L}+Z_{CA} lower.

For example, in order to make Z_{L}+Z_{CA} zero, the capacitance C_{A} is determined so that Z_{L}+Z_{CA}=jωL−j/(ωC_{A}) is zero. Such a C_{A} is equal to 1/(ω²L). Z_{L}+Z_{CA} does not necessarily need to be zero; when it is a sufficiently low value, a discharge to parts other than the parallel flat-plates can be substantially suppressed.

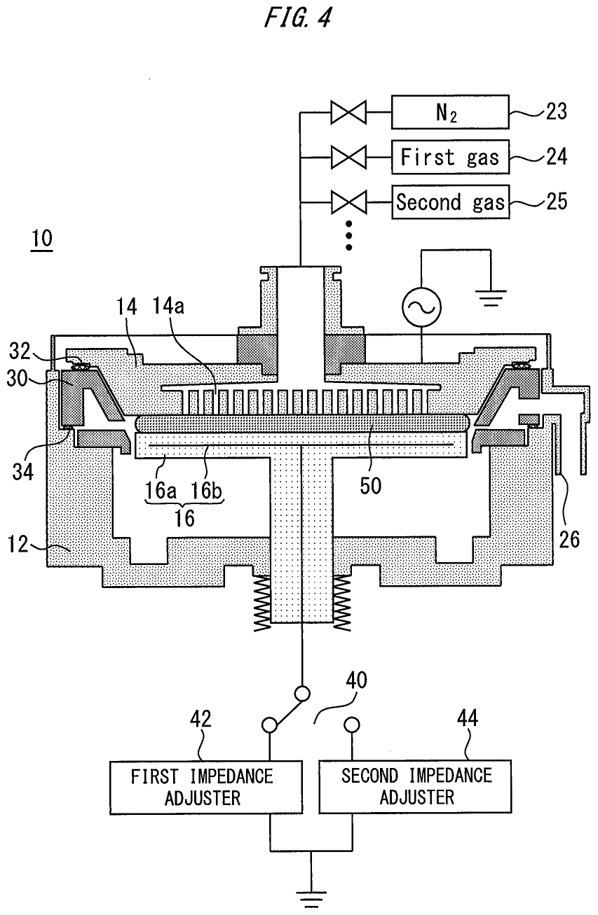

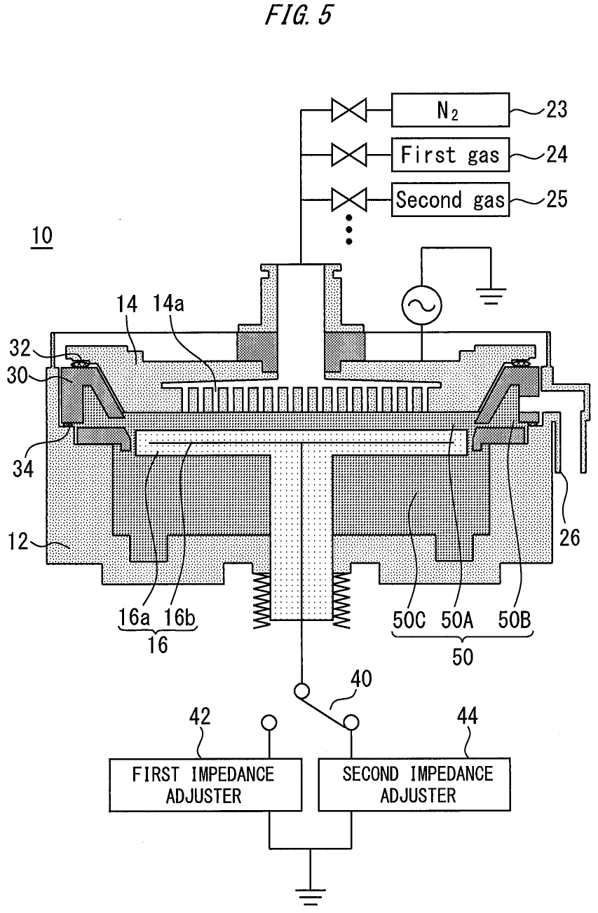

FIG. 4 shows plasma in plasma treatment or a normal cleaning by using the first impedance adjuster 42. Plasma 50 is generated between the metal plate 14 and the susceptor 16; and at other parts, significant plasma is not generated.

On the other hand, the second impedance adjuster 44 in FIG. 2A is provided so as to generate plasma in a region other than a space between the parallel flat-plates in the chamber. The second impedance adjuster 44 increases the impedance from the susceptor 16 to GND. When the capacitance of the second capacitor 44a is defined as C_{B} and the impedance provided by the capacitance C_{B} is defined as Z_{CB}, Z_{L}+Z_{CB} is set to be a larger value. Concretely, the capacitance C_{B} is designed so as to obtain Z_{L}+Z_{CB}>Z_{L}+Z_{CA}. Then, the electrode 16b and the second impedance adjuster 44 are connected by the selection device 40, gas is supplied into the chamber, and an RF power is applied to the metal plate 14; thereby generating plasma in the chamber.

At this time, the impedance from the susceptor 16 to the GND is high and therefore, in addition to a discharge between the parallel flat-plates, or instead of it, a discharge occurs between the metal plate 14 and the chamber 12. Accordingly, when the electrode 16b is grounded by the second impedance adjuster 44, plasma is generated in a wide range in the chamber.

FIG. 5 shows plasma in wide-range cleaning by using the second impedance adjuster 44. Plasma 50 is generated in almost all regions of the chamber 12. According one example, the plasma 50 includes: plasma 50A generated between the metal plate 14 and the susceptor 16; plasma 50B generated in the exhaust duct 30; and plasm 50C generated below the susceptor 16. Such plasma 50 as described above enables cleaning in a wide range.

Thus, the plurality of impedance adjusters is provided for adjusting the impedance from the susceptor to the GND so as to freely change a position where plasma is generated. The first capacitor 42a and second capacitor 44a in FIG. 2A are examples of the plurality of impedance adjusters; and a plurality of impedance adjusters having another configuration can be provided.

FIG. 2B shows another example of a plurality of impedance adjusters. The plurality of impedance adjusters includes: a first impedance adjuster 42 having a capacitor 42b; and a second impedance adjuster 44 having only wiring 44b. In this case, a wide-range cleaning is performed while an electrode 16b is grounded via the wiring 44b. When a sufficiently high impedance is obtained only by an impedance Z_{L} of the electrode 16b, the second impedance adjuster 44 only needs wiring.

FIG. 3A shows yet another example of a plurality of impedance adjusters. The plurality of impedance adjusters includes: a first impedance adjuster 42 having a capacitor 42c; and a second impedance adjuster 44 having a coil 44c. In this case, the sum of the impedance of the second impedance adjuster 44 and the impedance Z_{L} of the electrode 16b can be set to be larger than the impedance Z_{L} of the electrode 16b.

FIG. 3B shows still yet another example of a plurality of impedance adjusters. The plurality of impedance adjusters includes: a capacitor 42d as a first impedance adjuster 42; and a parallel circuit 44d of a capacitor and a coil as a second impedance adjuster 44. In examples in FIGS. 2A, 2B and 3A, a capacitor or wiring is used as an impedance adjuster. However, an intended impedance can be obtained by using both the capacitor and coil for one impedance adjuster, depending on, for example, the frequency of an RF power applied to the metal plate 14.

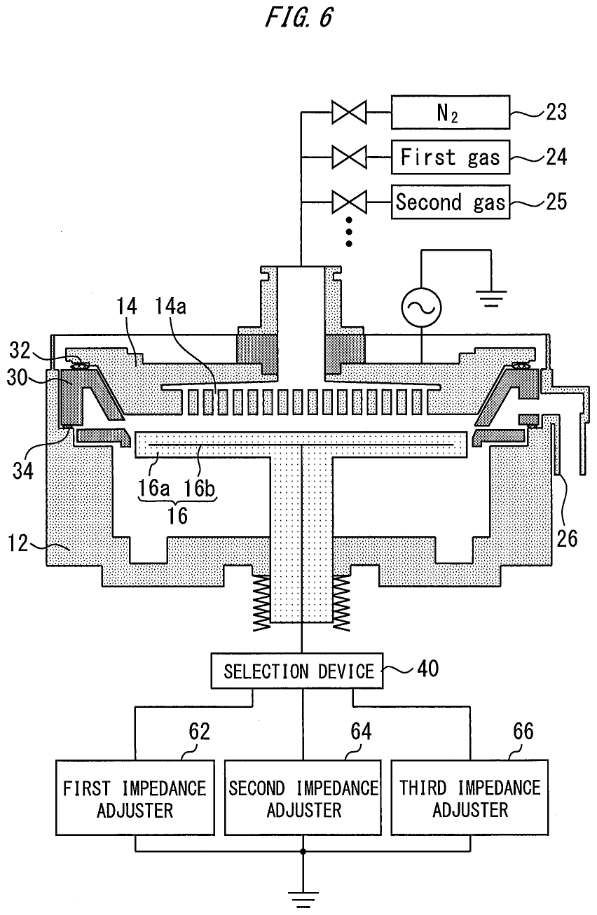

FIGS. 2A, 2B, 3A and 3B show configuration examples of a plurality of impedance adjusters; other circuits can also be adopted. FIG. 6 shows a configuration example of a plurality of impedance adjusters according to another example. In an example in FIG. 6, a first impedance adjuster 62, a second impedance adjuster 64, and a third impedance adjuster 66, which have different impedances, are provided as examples of a plurality of impedance adjusters. According to one example, when the electrode 16b is grounded via the first impedance adjuster 62, plasma is generated substantially only between parallel flat-plates; when the electrode 16b is grounded via the second impedance adjuster 64 or third impedance adjuster 66, plasma is generated also in regions other than the parallel flat-plates in the chamber. Differences in impedance between the second impedance adjuster 64 and the third impedance adjuster 66 can result in differences in plasma distribution within the chamber. Proper use of the second impedance adjuster 64 and third impedance adjuster 66 enables cleaning at an intended position. In addition, three or more impedance adjusters may be provided to achieve various plasma distributions.

A method of cleaning the inside of a chamber according to one example includes applying a high-frequency power to a metal plate 14 while an electrode 16b is grounded via a first impedance adjuster 42 to generate plasma in a first region between a susceptor 16 and a metal plate 14. The plasma generated in the first region can be used for, for example, forming a film on a substrate placed on the susceptor 16, etching the film on the substrate, and reforming the substrate. This plasma may also be used for cleaning the inside of the chamber. Gas to be supplied is changed according to the use purpose of the plasma.

When the electrode 16b is grounded via the first impedance adjuster 42, for example, hydrocarbon plasma is generated, thereby allowing a carbon film or a film including carbon to be formed on the substrate. For example, an HM carbon film requiring a high-temperature process can be formed. In carbon film formation, carbon is deposited also on the lower surface of the susceptor by diffusion. For the HM carbon, remote cleaning carried out with a halogen is difficult to perform.

A deposit on the surface of the lower surface of the susceptor cannot be removed by a normal cleaning in which plasma is generated only between parallel flat-plates.

In a method of cleaning the inside of a chamber, which has adopted the above configuration, a high-frequency power is applied to the metal plate 14 while the electrode 16b is grounded via the second impedance adjuster 44 of the impedance different from that of the first impedance adjuster 42 to generate plasma in a first region between parallel flat-plates and in a second region on the lower surface of the susceptor. This plasma is, for example, oxygen-based plasma. With this plasma, a deposit on the lower surface of the susceptor 16 can be removed. In another example, adjusting the impedance of the second impedance adjuster 44 or using the third impedance adjuster allows plasma to be generated in the first region and second region, and also in the third region in the exhaust duct 30.

In a wide-range cleaning using the second impedance adjuster 44, adjusting the impedance of the second impedance adjuster 44 allows plasma to be generated at any position of the chamber. The above-described normal cleaning and wide-range cleaning, oxygen-based plasma can be generated.

In one example, the pressure inside the chamber was set to 650 Pa, HRF was set to 2500 W, the temperature of the metal plate 14 was set to 240° C., the temperature of the susceptor 16 was set to 650° C., and the temperature of a wall surface of the chamber 12 was set to 240° C. while 7.6 slm O₂ and 2.4 slm Ar were being supplied between parallel flat-plates having a gap of 14.5 mm. Under this condition, when the electrode 16b was grounded by the first capacitor 42a with the capacitance of the first capacitor 42a in FIG. 2A being set to 1000 pF, no discharge occurred on the lower surface side of the susceptor. However, under the same condition, when the electrode 16b was grounded by the second capacitor 44a with the capacitance of the second capacitor 44a in FIG. 2A being set to 25000 pF, discharge occurred on the lower surface side of the susceptor.

1. A substrate treatment apparatus, comprising:
a chamber;
a susceptor provided in the chamber and having an electrode therein;
a metal plate facing the susceptor;
a plurality of impedance adjusters having different impedances; and
a selection device configured to connect one of the plurality of impedance adjusters to the electrode.

2. The substrate treatment apparatus according to claim 1, wherein
the plurality of impedance adjusters includes a first impedance adjuster having a first capacitor and a second impedance adjuster having a second capacitor.

3. The substrate treatment apparatus according to claim 1, wherein
the plurality of impedance adjusters includes a first impedance adjuster having a capacitor and a second impedance adjuster having only wiring.

4. The substrate treatment apparatus according to claim 1, wherein
the plurality of impedance adjusters includes a first impedance adjuster having a capacitor and a second impedance adjuster having a coil.

5. The substrate treatment apparatus according to claim 1, wherein
the plurality of impedance adjusters includes a parallel circuit of a capacitor and a coil.

6. The substrate treatment apparatus according to claim 1, comprising:
an AC power supply connected to the metal plate; and wherein
the plurality of impedance adjusters includes a first impedance adjuster and a second impedance adjuster;
the sum of the impedance of the first impedance adjuster and the impedance of the electrode is smaller than the impedance of the electrode; and
the sum of the impedance of the second impedance adjuster and the impedance of the electrode is larger than the impedance of the electrode.

7. The substrate treatment apparatus according to claim 1, wherein
the metal plate is a shower head having slits.

8. A cleaning method, comprising:
applying a high-frequency power to a metal plate facing a susceptor in a chamber while an electrode of the susceptor is grounded via a first impedance adjuster to generate plasma in a first region between the susceptor and the metal plate; and
applying a high-frequency power to the metal plate while the electrode is grounded via a second impedance adjuster of an impedance different from that of the first impedance adjuster to generate plasma in the first region and a second region, the second region being on a lower surface side of the susceptor.

9. The cleaning method according to claim 8, wherein
when plasma is generated in the second region, plasma is generated also in a third region in an exhaust duct provided so as to enclose the susceptor.

10. The cleaning method according to claim 8, wherein
a substrate placed on the susceptor is treated with plasma, the plasma being generated in the first region while the electrode is grounded via the first impedance adjuster.

11. The cleaning method according to claim 10, wherein
when the electrode is grounded via the first impedance adjuster to generate plasma in the first region, hydrocarbon plasma is generated; and
when the electrode is grounded via the second impedance adjuster to generate plasma in the first region and the second region, oxygen-based plasma is generated.
